(19) United States
(12) Patent Application Publication
(10) Pub. No.: US 2011/0038093 A1
(43) Pub. Date: Feb. 17, 2011

(54) TURNABLE CAPACITOR AND SWITCH USING MEMS WITH PHASE CHANGE MATERIAL

(75) Inventors: Yukiko Furukawa, Kimitsu (JP); Klaus Reimann, Eindhoven (NL); Christina Adriana Renders, Riethoven (NL); Liesbeth Van Pieterson, Heeze (NL); Jin Liu, Amersfoort (NL); Friso Jacobus Jedema, Eindhoven (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/988,223

(22) PCT Filed: Apr. 17, 2009
(86) PCT No.: PCT/IB2009/051606

§ 371 Date: Oct. 15, 2010

(30) Foreign Application Priority Data
Apr. 18, 2008 (EP) 08154837.2

(51) Int. Cl. H01G 7/00; H01L 29/93; H01L 21/02

(52) U.S. Cl. 361/277; 257/3; 438/379; 257/E29.344; 257/E21.008

(57) ABSTRACT

The present invention relates to a MEMS, being developed for e.g. a mobile communication application, such as switch, tunable capacitor, tunable filter, phase shifter, multiplexer, voltage controlled oscillator, and tunable matching network. The volume change of phase-change layer is used for a bi-stable actuation of the MEMS device. The MEMS device comprises at least a bendable cantilever, a phase change layer, and electrodes. A process to implement this device and a method for using is given.

### FIELD OF THE INVENTION

The present invention relates to a MEMS, being developed for e.g. a mobile communication application, such as switch, tunable capacitor, tunable filter, phase shifter, multiplexer, voltage controlled oscillator, and tunable matching network. The volume change of phase-change layer is used for a bi-stable actuation of the MEMS device. The MEMS device comprises at least a bendable cantilever, a phase change layer, and electrodes. A process to implement this device and a method for using is given.

An example of the prior art is a capacitive RF MEMS switch, which can gain relatively large change of capacitance, due to change of distance or area between electrodes. However, these require an actuator to be controlled and response is slow. Another example is a tunable capacitor using ferroelectric or paraelectric material. The dielectric constant of these materials can be tuned by applying an electric field. Although these have a quick response for the electric field, the tuning ratio is relatively small.

### BACKGROUND OF THE INVENTION

U.S. Pat. No. 6,954,348 B1 discloses various embodiments of tunable capacitors. One embodiment is in the form of a tunable capacitor having a pair of stationary capacitor electrodes that are fixed to and disposed the same distance above a substrate in the vertical dimension. A tuning element is suspended above the substrate by an elevation system that accommodates movement of the tuning element in the vertical dimension. Changing the capacitance of the tunable capacitor is accomplished by moving the tuning element in the vertical dimension.

We note that U.S. Pat. No. 6,954,348 B1 describes many structures of tunable MEMS capacitors.

However, for instance in FIGS. 4c and 4d, at least two different materials are used for providing a pre-stressed condition to bent a beam. It is well known for tunable MEMS to move a beam mechanically for tuning Further, no material, nor method (electrical, thermal . . . ) to move a beam, is mentioned in the patent. Therefore the beam has a limited tunability and limited accuracy.

WO0161848 A1 discloses an arrangement for an integrated tunable resonator for radio and a method for producing the same. In particular it relates to an RF resonator realized with a micro-mechanical tunable capacitor with high Q-(quality factor) value and a method for fabricating the same. In one particular embodiment of the arrangement the first conducting layer forms the first capacitor electrode, and/or the electrodes to create the electrostatic force on the movable micro-mechanical structure, and the interconnecting wire between the inductor coil and the capacitor electrode. It presents a substantial improvement to the linearity, power consumption, occupation space and reliability of RF resonator circuits.

US2004012299 A1 discloses an assembly of variable capacitance as well as a method of operating the assembly. In the assembly, a variable coverage or a variable distance of at least one first and one second electrically conductive region forms a variable capacitor. The first electrically conductive region is configured on or in a substrate and said second electrically conductive region is configured on or in an actuator element of a first micro-mechanical actuator. The actuator is disposed on the substrate in such a way that it can perform a movement of the actuator element with the second region along a surface of the substrate at different positions relative to the first region, at which positions the second region overlaps the first region at least partly. Moreover, holding means are provided which are capable of pulling or pushing the actuator element in the different positions towards the substrate or a mechanical stop on the substrate, and of holding it in these positions. The assembly serves to implement a variable capacitance that presents a high stability in resistance to outside influences according to its respective setting.

WO2007084070 discloses a thermally controlled switch with high thermal or electrical conductivity. Microsystems Technology manufacturing methods are fundamental for the switch that comprises a sealed cavity formed within a stack of bonded wafers, wherein the upper wafer comprises a membrane assembly adapted to be arranged with a gap to a receiving structure. A thermal actuator material, which preferably is a phase change material, e.g. paraffin, adapted to change volume with temperature, fills a portion of the cavity. A conductor material, providing a high conductivity transfer structure between the lower wafer and the rigid part of the membrane assembly, fills another portion of the cavity. Upon a temperature change, the membrane assembly is displaced and bridges the gap, providing a high conductivity contact from the lower wafer to the receiving structure.

U.S. Pat. No. 6,624,730 B1 discloses a micro-relay device formed on a silicon substrate wafer for use in opening and closing a current path in a circuit. A pair of electrically conducting latching beams is attached at their proximal ends to terminals on the substrate. Proximal ends of the beams have complementary shapes, which releasably fit together to latch the beams and close the circuit. A pair of shape memory alloy actuators are selectively operated to change shapes which bend one of the beams in a direction which latches the distal ends, or bend the other beam to release the distal ends and open the circuit. The micro-relay is bistable in its two positions, and power to the actuators is applied only for switching it open or closed.

Shape memory alloys have the disadvantage that they must be kept at a required temperature for actuation. This requires stand-by power. A clever design might allow for bi-stability, like a bimetallic actuator, optionally using hysteretic effects too. Phase change materials are known per se. Phase change materials change their volume significantly during crystallographic phase transition. For instance, a typical phase change material such as Ag_{5.5}In_{6.5}Sb₅₉Te₂₉, Ge₂Sb₂Te₅ and Ge₄Sb₁Te₅ decrease about 5-9% in volume, when phase changing from amorphous phase to crystalline phase, at a temperature in a range of 130-200° C., as shown in FIG. 1.

However, prior art semiconductor devices comprising a MEMS, a top electrode, and a bottom electrode, and optionally at least one tunable capacitor, still suffer from various disadvantages.

First, a high tunability of the MEMS is not possible.

Also, prior art capacitors and MEMS have a relatively large size. Such capacitors further typically do not allow a control of temperature. If temperature is controlled typically an extra scheme for controlling temperature is necessary.

Next, a combination of electric and thermal tuning is not possible.

Thus there still is a need for improved semiconductor devices comprising a MEMS.

The present invention is aimed at solving one or more of the above disadvantages.

### SUMMARY OF THE INVENTION

The present invention relates to a semiconductor device comprising at least one tunable capacitor, which capacitor comprises a MEMS, a top electrode, a bottom electrode, a volume forming a beam having sides comprising a phase change material, and preferably a dielectric material in between the phase change material and an electrode, a method of operating the same, and a method of manufacturing the same.

### DETAILED DESCRIPTION OF THE INVENTION

In a first aspect the invention relates to a semiconductor device comprising a MEMS, a first electrode, a second electrode, and a volume forming a beam comprising a phase change material, wherein the volume preferably comprises a dielectric material in contact with the phase change material and preferably comprises a conducting layer, wherein the device is arranged to electrically and controllably change the volume of the phase change material by going from one phase to another, thereby changing the volume by 5-25%, preferably higher than 9%, such as higher than 15%, wherein said change preferably occurs within a temperature range of 50-500° C., more preferably from 80-350° C., more preferably from 100-200° C., such as from 130-170° C.

The present MEMS itself is regarded to function as a micro-actuator, being of a small size and implementing a process. As such it can be used in a switch, in a tunable capacitor, or as a mirror, if provided with a reflective layer, or combinations thereof Examples of MEMS structures are given in the drawings. It is noted that in fact the MEMS may be smaller than one micron, and therefore may also refer to a Nano type MEMS, also referred to as NEMS. A NEMS has advantages in terms of heat dissipation, being better if the NEMS is relatively smaller. As such, a further advantage is that a NEMS or a MEMS is easily integrated in CMOS technology.

For actuation, a first and a second electrode need to be present, the first electrode functioning as entrance and the second electrode functioning as exit of the electric current, or vice versa. The electrical resistivity of the material through which a current runs, such as of the phase change material and of the conducting material, causes the PCM to warm up. Preferably the current runs through the PCM.

The PCM may have any form, e.g. it may be in the form of a single electric return or entrance path (typically in combination with a conducting layer), of a meander structure, of a u-shaped electrical path, of a layer on top of a conductor, which conductor warms up the PCM indirectly by an electrical current applied, or combinations thereof.

For effective use of the present MEMS or micro-actuator the PCM should change significantly in volume. It is noted that not many materials in general, let alone PCM's, qualify for this purpose, as the volume change thereof, going from a first to a second phase, is too small. Further, not many materials in general qualify to be changed in a controllable manner, let alone by applying an electrical current. Such as change should also be reversible, as the material should be able to return to its initial situation, that is with unchanged volume.

The present phase change material changes it phase at a certain temperature or within a certain temperature range, going from a first phase to a second phase, such as from an amorphous phase to a crystalline phase, or vice versa, or from a first crystalline phase to a second crystalline phase.

The phase change is preferably accomplished by applying an electrical current, which current causes the present phase change material to heat up, or by absence of said current, to cool down. The phase change results in a thermodynamically metastable or stable situation of the material, i.e. no phase change will take place by itself within a normal applicable time limit, such as minutes, or hours, or even years. As a result of actuation the volume of the present phase change material (PCM) will have changed. The present process is well controllable, by applying an electrical current which heats up the PCM to the required temperature, or by cooling. Furthermore, the present process is relatively quick, i.e. it takes place within a few microseconds. Adequate design allows for even shorter switching times. Examples of designs are given in the drawings. Therewith, switching times in the order of a few microseconds have been achieved. In other words, the present invention refers to a bi-stable actuation. It means that no electrical voltage is needed to maintain the position of the beam. An on current pulse is enough for that purpose. A (bi-)stable actuation is therefore very simple. A continuous actuation is possible by e.g. partial crystallization. It may also be achieved by segmenting the phase change layer and actuating a part of the beam, for instance by a multi-step actuation, for instance leading to multiple positions of the beam, or for instance leading to a stepped capacitor.

Thus, the volume change of the present PCM allows for a design wherein the beam may be switched rapidly and in a controlled manner, by applying an electrical current. Preferably a phase change material with a very high volume change, upon phase changing, is used, which volume change may be negative or positive. It is further preferred that the phase change or volume change is achieved at temperatures which may be established locally, by applying said current, which temperatures are not too high, and which are not too low. A too high temperature is more difficult to reach, be not very well controllable, not being reliable and may further have a detrimental effect on optional other components being present in the semiconductor device. A too low temperature may already be reached by environmental circumstances, such as the outside temperature, making the control of the switching more difficult.

The volume forming a beam can be a bendable cantilever.

The volume change of the phase-change layer is used for a bi-stable actuation of the MEMS device.

Preferably the PCM is encapsulated to prevent the material against environmental influences, such as oxidation, and further to control phase transition better. If the PCM is melted it might flow and by encapsulation such a flow is prevented. As such the lifetime as well as cycle-time are improved. Details of how to make such a configuration can be found in co-pending EP07115899 in the name of the same applicant, entitled “An electronic component, and a method of manufacturing an electronic component” (internal reference 81054762EP01). The disclosure thereof is hereby incorporated by reference.

Advantages of the tunable capacitor and switch according to the invention are amongst others:
a high tunability, which may depend on material composition, such as having an εₘₐₓ/εₘᵢₙ of more than 5, preferably more than 10, such as more than 20, or even more than 50, such as more than 100;
it retains a stable position of the capacitance;
it has a smaller size compared to a capacitive RF MEMs switch, e.g. a capacitive RF MEMS switch behaving like a mass-spring system, actuated by electrostatic force, which actuation is a function of the capacitance and the bias voltage. In order to have a big capacitance change, a large area of electrodes facing each other is needed in the prior art. (see e.g. U.S. Pat. No. 6,954,348 B1 as an example thereof). In the present invention a very high strain (˜9% deformation) of material itself is used, which allows to make a comparably small size device.
it is possible to control temperature. In the present invention the temperature of the beam (comprising a phase change material) is controlled by applying a current through the material for the beam. Further, a same or similar scheme for controlling temperature for the system may be used, wherein an array present can be used as a heater, allowing a high accuracy and reliability of the present tunable capacitor. It is noted that typically electrical properties are in the present respect detrimentally affected by temperature, for instance, electrical resistivity of metals increases with temperature, while the resistivity of semiconductors decreases with increasing temperature in general. Therefore, controlling temperature can provide an accurate electrical response, independent of circumstances, e.g. one of a resistor or capacitor present may be a temperature sensor, as shown in e.g. FIG. 4.
the present invention provides a combination of electric and thermal tuning.

In a preferred embodiment the present invention relates to a semiconductor device, wherein the phase change material comprises a Group V and Group VI element, preferably a composition comprising Sb-M, wherein M being one or more elements selected from the group of Ge, In, Ag, Ga, Te, Zn, Sn, for instance; Ag_{5.5}In_{6.5}Sb₅₉Te₂₉, Ge_{0.08-0.4}Sb_{0.1-0.33}Te_{0.5-0.66}, Ge₂Sb₂Te₅, Ge₁Sb₂Te₄, Ge₁Sb₄Te₇ and Ge₄SbᵢTe₅, and combinations thereof. These materials have a large volume change, such as more than 5%, which volume change is achieved at relatively low temperatures, e.g. around 150° C. Furthermore, the phase transition of these materials is well controlled, e.g. by applying an electrical current which current forms heat. It is envisaged that also any phase change material, which can provide a high volume change at a temperature being close enough to room temperature, such as organic or polymer material, may be used, as well as combinations thereof.

In a yet further preferred embodiment the present invention relates to a semiconductor device, further comprising a bottom or top electrode present on one or more sides of the phase change material and one electrode on one or more sides of the dielectric material, preferably at a side enabling electrical contact with the second electrode. As such the device forms a switch, operable by an electrical current. For examples thereof see e.g. FIGS. 2-4.

In a yet further preferred embodiment the present invention relates to a semiconductor device, wherein the phase change material changes in volume by going from one phase to another by a negative amount or by a positive amount.

In a yet further preferred embodiment the present invention relates to a semiconductor device, wherein the beam is arranged to allow movement in a horizontal direction or in a vertical direction. Depending on requirements the device may need to operate in a horizontal or in a vertical direction, or combinations thereof.

In a second aspect, the present inventions relates to a method of manufacturing a semiconductor device according to the invention, comprising the steps of:
providing a substrate, such as a Si wafer, preferably a (100) Si wafer;
deposition of a dielectric layer, preferably with a thickness of 100 nm-1000 nm, such as 500 nm, preferably formed of Al₂O₃, Si₃N₄, SiO₂;
bottom electrode layer deposition, forming a layer, preferably with a thickness of 30 nm-300 nm, such as 100 nm, preferably formed of a conducting material, preferably formed of copper (Cu), tungsten (W), aluminum (Al), titanium (Ti), titanium nitride (TiN), gold (Au), platinum (Pt) and combinations thereof;
patterning said layer by standard optical lithography;
followed by etching of said layer forming the bottom electrode;
   sacrificial layer deposition, preferably with a thickness of 200 nm-2 μm, such as 500 nm, preferably formed of SiO₂, Si₃N₄, organic material like photo resist, low-k dielectric;
planarization of the sacrificial layer, preferably by CMP;
patterning and etching of the sacrificial layer to form a container shape;
   deposition and patterning through lithography and etching of a side electrode, preferably with a thickness of 20 nm-200 nm, such as 30 nm, preferably of a material comprising Cu, W, Al, Ti, TiN, Au, Pt and combinations thereof;
filling the container shape with phase change material, with a thickness of 20 nm-200 nm, preferably using a phase change materials which can give a high volume change as mentioned above, and combinations thereof;
thin dielectric insulation layer deposition, preferably with a thickness of 10-100 nm, preferably comprising a material such as TiO2, Al₂O₃, Si₃N₄, SiO₂, and combinations thereof, depending on which material is used as a sacrificial material, and opening of the side electrode by lithography and etching;
top electrode deposition, preferably having a thickness of 20-200 nm, such as 30 nm, preferably comprising a material such as Cu, W, Al, Ti, TiN, Au, Pt and combinations thereof, and patterning; and
removal of the sacrificial layer.

In a third aspect, the present inventions relates to a method of operating a semiconductor device according to the invention, comprising the steps of:
applying a voltage difference over the first electrode and second electrode;
changing the volume of the phase change material, thereby bending the beam; and
relieving the voltage difference.

Preferably the method of operating further comprises the steps of applying a second voltage difference over the first electrode and second electrode, thereby re-crystallizing the phase change material, and relieving the second voltage difference.

It is noted that one may refresh pulses in the case that the phase change material would degrade too fast.

In general the step of actuation or applying a voltage difference over the first electrode and second electrode may comprise the following steps:

1) Heat the PCM strongly, and thereafter cool the PCM fast, resulting in a first amorphous switch state;
2) Then heat moderately, keeping the PCM a short while at a given temperature resulting in a second recrystallized switch state, and then in order to obtain an optionally next movement of the beam,
3) back to step (1)
This is similar as for standard phase change switching.

The present invention is further elucidated by the following Figures and examples, which are not intended to limit the scope of the invention. The person skilled in the art will understand that various embodiments may be combined.

### BRIEF DESCRIPTION OF THE DRAWINGS

FIG. 1 shows temperature dependence of volume for phase change material.

FIG. 2a shows a structure of proposed tunable capacitor, single beam structure. (X-section).

FIG. 2b shows a structure of proposed tunable capacitor, single beam structure. (X-section)

FIG. 3 shows a structure of proposed tunable capacitor (top down)

FIG. 4 shows a part of the meander comb structure for the horizontal movement (X-section)

FIG. 5 shows a method of manufacturing a MEMS.

FIG. 6 shows an alternative embodiment in cross-section.

FIG. 7 shows an alternative embodiment for contacting the phase change material (top view).

FIG. 8 shows variations of the process flow.

### DETAILED DESCRIPTION OF THE DRAWINGS

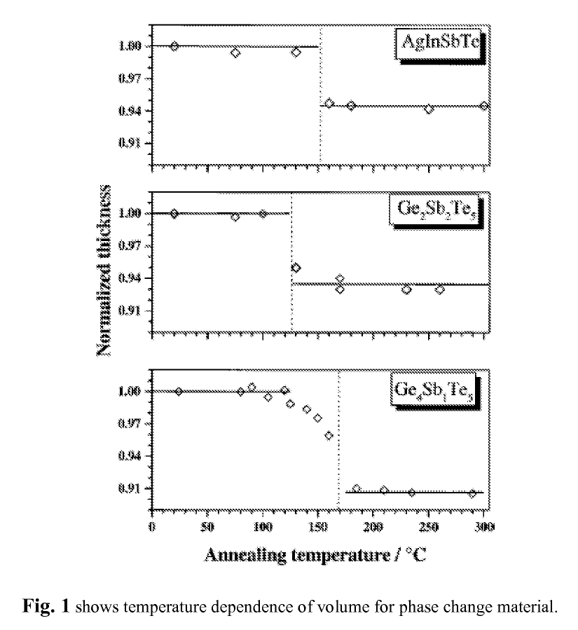

FIG. 1 shows temperature dependence of volume for phase change material.

Film thickness of AgInSbTe, Ge₂Sb₂Te₅ and Ge₄Sb₁Te₅ films as a function of increasing annealing temperature as measured by X-ray reflectometry. Crystallization, which leads to a sudden decrease in film thickness, is observed at 155° C. for AgInSbTe, 130° C. for Ge₂Sb₂Te₅ and 170° C. for Ge₄Sb₁Te₅. To facilitate a comparison of different data sets, all thicknesses are normalized with respect to the thickness of the as-deposited film. Crystallization leads to a 5.5% thickness decrease for AgInSbTe, a 6.5% thickness decrease for Ge₂Sb₂Te₅ and 9% thickness reduction for Ge₄SbᵢTe₅.

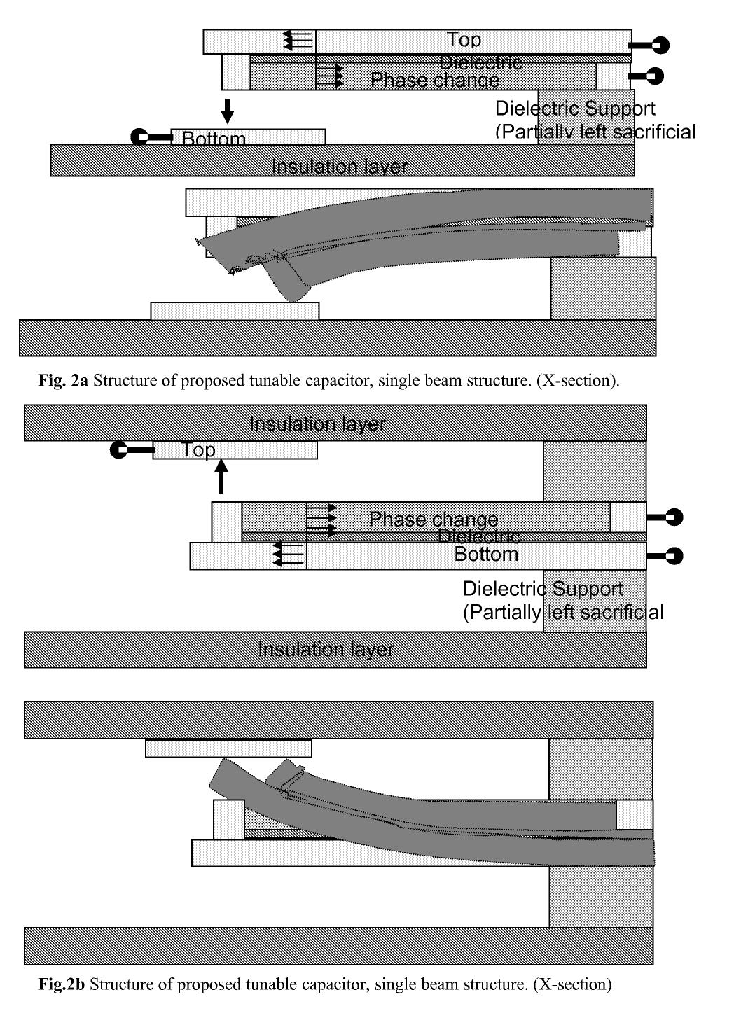

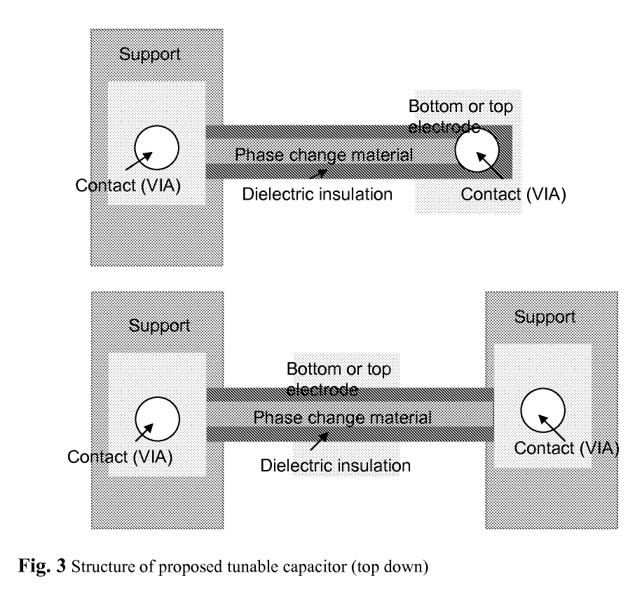

FIG. 2a Structure of proposed tunable capacitor, single beam structure. (X-section)

FIG. 2 a, b show X-sectional view of proposed structures. A beam is supported by a dielectric insulation, which can be a sacrificial layer intentionally left during removal of the sacrificial layer. In the beam an additional dielectric layer is inserted to insulate a phase change material against an electrode and in this way electric pulse (generating heat) can go through the phase change material without interruption of the electrode. It is noted that as an electrode typically has a lower resistivity than a phase change material, an electrical current will go through the metal instead, and it is preferred to separate the metal from the phase change material, by e.g. a dielectric, to heat the phase change material efficiently. Also a metal is a good heat conductor, which is beneficial for a fast cooling of the layer. Electric current heats a line or pillar-like structure of the phase change material. The phase change material contracts and causes a compression stress in optional other layers present, specifically between 20-500° C., which stress depends on the material used. The asymmetric (bi- or multi-layer) structure of the beam is essential for bending the beam by the tensile stress of the phase change material and the compressive stress of the other layers. The non-zero stress gradient in the layer stack causes the beam to bend (FIG. 2 (a2,b2)). The neutral plane (no stress) should be outside of the phase change layer for best performance. The situation can be optimized by choosing a compliant isolator between the metal electrode and the phase change material. This behavior depends on composition of materials of the beam, structure and the length of the beam.

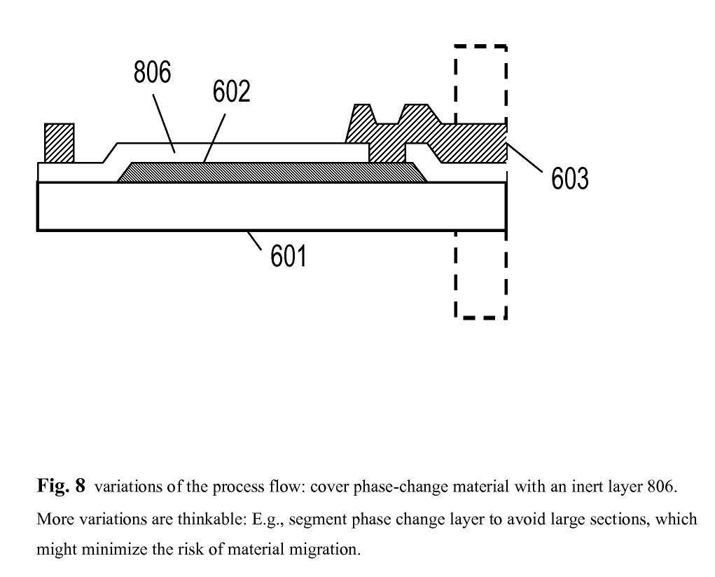

The current controls the bending of the beam and hence controls capacitance between electrodes or switching behavior. In order to reverse the crystal phase, the phase change material can be melted at 500-600° C., where after a quick cooling of the melting material forms amorphous phase. It is noted that typically this is a slow and irreversible process, specifically when large volumetric changes are involved and/or crystal lattice restructuring. It is therefore limited to specific relatively fast changing materials, such as those chosen in the present invention. Further a phase change may depend on the size of the material chosen. At present, the dimension of the beam is of nano- or micrometer order, that allowing the switching to be fast. The present invention provides the designs and materials to switch in less than a microsecond. This time is enough to set and reset the phase. The phase change material is being held with side electrodes or cover layers (FIG. 8) to keep the shape of the material when it melts. Another option could be to deposit the material in trenches, which lowers the risk of creep even lower, but involves more complicated processing steps. The area and the length of the phase change material should be minimized so that the material can be melted completely with a certain speed. For instance, if the thickness of the supporting insulation layer is from 200 nm-2 μm, preferably from 300 nm-2 μm, more preferably from 300 nm-1 μm, such as 500 nm. The total thickness of the beam is from 50 nm-500 nm, preferably from 70 nm-500 nm, more preferably from 70 nm-250 nm, such as 100 nm. The length of the phase material can be from 1 um-30 μm, preferably from 1 um-10 μm, more preferably such as around 3 um, to switch between electrodes. These numbers have further been confirmed by a model calculation. A capacitive output is gained between the top electrode and the bottom electrode. The integration of this capacitor is similar as any other MEMS structure and the phase change material, compatible with standard IC processing. FIG. 3 shows a top-down view of a proposed structure; (a) an example for a bean supported only one side (single beam structure), (b) a beam supported both side.

FIG. 2b Structure of proposed tunable capacitor, single beam structure. (X-section)

FIG. 3 Structure of proposed tunable capacitor (top down)

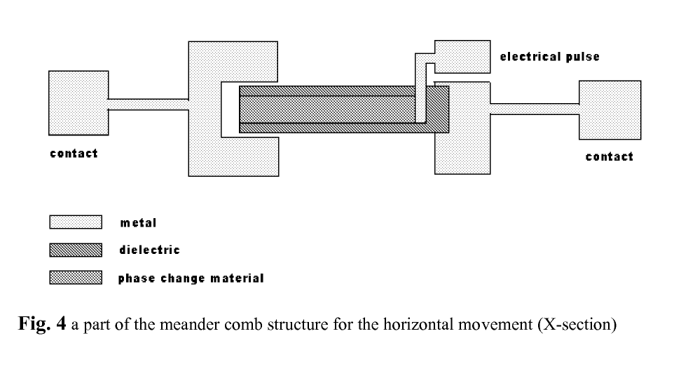

FIG. 4 a part of the meander comb structure for the horizontal movement (X-section)

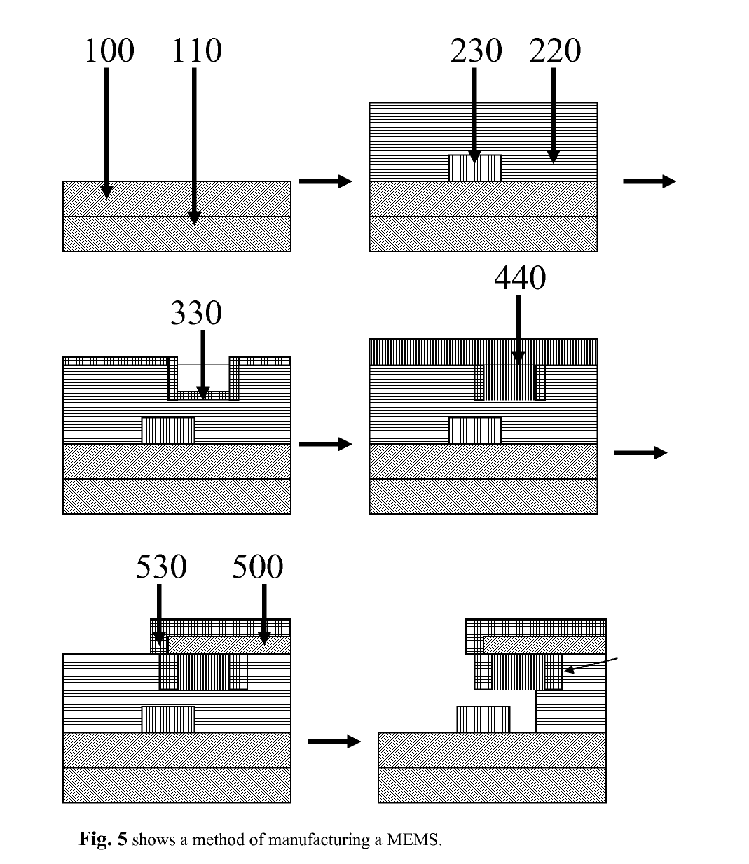

FIG. 5 shows a method of manufacturing a MEMS. In a first step a dielectric material (100) is deposited on a substrate (110), such as Si. Than a bottom electrode (230) is formed. On top of the dielectric layer and bottom electrode a sacrificial layer (220) is deposited, typically being a dielectric layer. Than a container for a side electrode (330) is formed by patterning and etching the sacrificial layer, followed be depositing a conducting material. The conducting material is than partly removed, e.g. by etching and/or planarization. Than a further layer (440), such as a Phase Change Material (PCM) layer is deposited and thereafter planarized, such as by CMP. A further dielectric layer (500) is deposited, patterned and etched. Than a further conducting layer (530), forming part of the top electrode is deposited, patterned and etched. Finally the sacrificial layer is partly removed by etching thereof The contact to the right electrode is made in the same way as to the left electrode by the metallization 530, but at the side of the beam. The layers 500 and 530 need to be patterned anyhow so that this contacts are made in the same mask and process steps. The top metallization 530 can be used for further routing the electrical currents and signals to control units and signal pads.

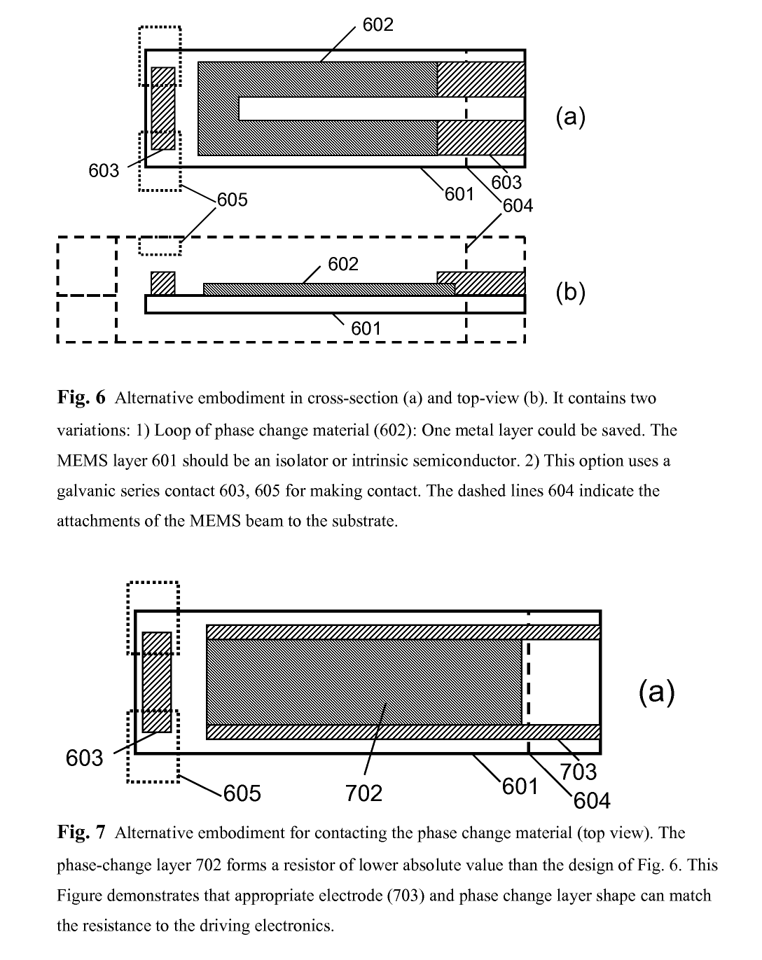

FIG. 6 shows an alternative embodiment in cross-section (a) and top-view (b). It contains two variations: 1) Loop of phase change material (602): One metal layer could be saved. The MEMS layer 601 should be an isolator or intrinsic semiconductor. 2) This option uses a galvanic series contact 603, 605 for making contact. The dashed lines 604 indicate the attachments of the MEMS beam to the substrate.

FIG. 7 shows an alternative embodiment for contacting the phase change material (top view). The phase-change layer 702 forms a resistor of lower absolute value than the design of FIG. 6. This Figure demonstrates that appropriate electrode (703) and phase change layer shape can match the resistance to the driving electronics.

FIG. 8 shows variations of the process flow: cover phase-change material with an inert layer 806. More variations are thinkable: E.g., segment phase change layer to avoid large sections, which might minimize the risk of material migration.

1. Semiconductor device comprising a MEMS, a first electrode, a second electrode, and a volume forming a beam comprising a phase change material, wherein the beam preferably comprises a dielectric material in contact with the phase change material and preferably comprises a conducting layer, wherein the device is arranged to electrically and controllably change the volume of the phase change material by going from one phase to another, thereby changing the volume by 1-25%, wherein said change occurs within a temperature range of 50-500° C.

2. Semiconductor device according to claim 1, wherein the phase change material comprises a Group V and Group VI element, preferably a composition comprising Sb-M, wherein M being one or more elements selected from the group of Ge, In, Ag, Ga, Te, Zn, Sn.

3. Semiconductor device according to claim 1, further comprising a bottom or top electrode present on one or more sides of the phase change material and one electrode on one or more sides of the dielectric material, preferably at a side enabling electrical contact with a second electrode.

4. Semiconductor device according to claim 1, wherein the phase change material changes in volume by going from one phase to another by a negative amount or by a positive amount.

5. Semiconductor device according claim 1, wherein the beam is arranged to allow movement in a horizontal direction or in a vertical direction.

6. Method of manufacturing a semiconductor device according to claim 1, comprising the steps of:
providing a substrate, such as a Si wafer;
deposition of a dielectric layer, preferably with a thickness of 100 nm-1000 nm, such as 500 nm, preferably formed of Al₂O₃, Si₃N₄, SiO₂;
bottom electrode layer deposition, forming a layer, preferably with a thickness of 30 nm-300 nm, such as 100 nm, preferably formed of a conducting material, preferably formed of copper (Cu), tungsten (W), aluminum (Al), titanium (Ti), titanium nitride (TiN), gold (Au), platinum (Pt) and combinations thereof;
patterning said layer by standard optical lithography;
followed by etching of said layer forming the bottom electrode;
sacrificial layer deposition, preferably with a thickness of 200 nm-2 μm, such as 500 nm, preferably formed of SiO₂, Si₃N₄, organic material like photo resist, low-k dielectric;
planarization of the sacrificial layer, preferably by CMP;
patterning and etching of the sacrificial layer to form a container shape;
deposition and patterning through lithography and etching of a side electrode, preferably with a thickness of 20 nm-200 nm, such as 30 nm, preferably of a material comprising Cu, W, Al, Ti, TiN, Au, Pt and combinations thereof;
filling the container shape with phase change material, with a thickness of 20 nm-200 nm, preferably using a phase change materials which can give a high volume change as mentioned above, and combinations thereof;
thin dielectric insulation layer deposition, preferably with a thickness of 10-100 nm, preferably comprising a material such as TiO2, Al₂O₃, Si₃N₄, SiO₂, and combinations thereof, depending on which material is used as a sacrificial material, and opening of the side electrode by lithography and etching;
top electrode deposition, preferably having a thickness of 20-200 nm, such as 30 nm, preferably comprising a material such as Cu, W, Al, Ti, TiN, Au, Pt and combinations thereof, and patterning; and
removal of the sacrificial layer.

7. Method of operating a semiconductor device according to claim 1, comprising the steps of:
applying a voltage difference over the first electrode and second electrode;
changing the volume of the phase change material, thereby bending the beam; and
relieving the voltage difference.

8. Method according to claim 7, further comprising the steps of applying a second voltage difference over the first electrode and second electrode, thereby re-crystallizing the phase change material, and relieving the second voltage difference.
